(19) United States
(12) Patent Application Publication
(10) Pub. No.: US 2022/0084798 A1
(43) Pub. Date: Mar. 17, 2022

(54) PLASMA PROCESSING APPARATUS AND ELECTRODE STRUCTURE

(71) Applicant: Tokyo Electron Limited, Tokyo (JP)

(72) Inventors: Hachishiro IIZUKA, Yamanashi (JP); Yasuaki TANIIKE, Yamanashi (JP)

(21) Appl. No.: 17/425,026

(22) PCT Filed: Jan. 21, 2020
(86) PCT No.: PCT/JP2020/001835

§ 371 Date: Jul. 22, 2021

(30) Foreign Application Priority Data
Feb. 4, 2019 (JP) 2019-018102

(51) Int. Cl. H01J 37/32

(52) U.S. Cl. CPC H01J 37/32651; H01J 37/32449; H01J 2237/332; H01J 37/32091; H01J 37/32715; H01J 37/32568

(57) ABSTRACT

This plasma processing device is provided with an electrode structure. The electrode structure comprises a stage, a support portion, a first dielectric, a second dielectric, a third dielectric, a first shield, a second shield, and a third shield. The support portion is connected to a lower portion of the stage. The first dielectric is disposed in a peripheral region of an upper surface of the stage. The second dielectric is disposed on a side surface and a lower surface of the stage. The third dielectric is disposed around the support portion. The first shield is disposed on the upper surface of the first dielectric around a body to be processed mounted on the stage. The second shield is connected to the first shield and disposed on the side surface of the stage, with the second dielectric therebetween. The third shield is connected to the second shield and disposed on the lower surface of the stage and around the support portion, with the second dielectric and the third dielectric therebetween. The third shield is grounded.

### TECHNICAL FIELD

Various aspects and embodiments of the present disclosure relate to a plasma processing apparatus and an electrode structure.

### BACKGROUND

Patent Document 1 discloses, for example, a film forming apparatus in which a stage 2 on which a wafer W is placed is raised by an elevating mechanism, the wafer W is processed at the position after the raising, the stage 2 is lowered by the elevating mechanism after the processing, and the wafer W is transferred at the position after the lowering.

### PRIOR ART DOCUMENT

### Patent Document

Patent Document 1: International Publication No. WO 2014/178160

### SUMMARY OF THE INVENTION

### Problem to be Solved

The present disclosure provides a plasma processing apparatus and an electrode structure capable of suppressing abnormal discharge in a processing container.

### Means to Solve the Problem

One aspect of the present disclosure is a plasma processing apparatus including a processing container, a shower head, an electrode structure, and a power supply. The shower head is disposed in the processing container, functions as an upper electrode, and supplies a gas used to generate plasma into the processing container. The electrode is disposed in the processing container and has an upper surface on which a workpiece is placed. The power supply supplies a radio-frequency power to the electrode structure. Further, the electrode structure includes a stage, a support, a first dielectric, a second dielectric, a third dielectric, a first shield, a second shield, and a third shield. The stage functions as a lower electrode facing the shower head, and has an upper surface on which the workpiece is placed. The support is connected to a lower portion of the stage and supports the stage. The first dielectric is disposed in a peripheral edge region of the upper surface of the stage. The second dielectric is disposed on a side surface and a lower surface of the stage. The third dielectric is disposed around the support. The first shield is an upper surface of the first dielectric, and is disposed in the peripheral edge of the stage. The second shield is connected to the first shield, and is disposed on the side surface of the stage across the second dielectric. The third shield is connected to the second shield, and is disposed on the lower surface of the stage and around the support across the second dielectric and the third dielectric. Further, plasma is generated between the shower head and the stage, and the workpiece placed on the stage is processed by the generated plasma. Further, the third shield is grounded.

### Effect of the Invention

According to various aspects and embodiments of the present disclosure, abnormal discharge in the processing container may be suppressed.

### BRIEF DESCRIPTION OF THE DRAWINGS

FIG. 1 is a schematic cross-sectional view illustrating an example of a film forming apparatus according to an embodiment of the present disclosure.

FIG. 2 is a schematic cross-sectional view illustrating an example of an electrode structure according to the present disclosure.

FIG. 3 is an enlarged cross-sectional view illustrating an example of a structure in the vicinity of a peripheral edge of a stage.

FIG. 4 is a view illustrating an example of an equivalent circuit.

FIG. 5 is a view illustrating another example of the equivalent circuit.

### DETAILED DESCRIPTION TO EXECUTE THE INVENTION

Hereinafter, embodiments of a plasma processing apparatus and an electrode structure disclosed herein will be described in detail with reference to the drawings. The plasma processing apparatus and the electrode structure disclosed herein are not limited to the embodiments below.

A processing chamber in which a wafer is processed and a transfer chamber in which the wafer is transferred are separated by a stage on which the wafer is placed. However, the processing chamber and the transfer chamber are not separated airtightly, but the two spaces are in communication with each other. As a result, the gas supplied into the processing chamber or the particles generated in the processing chamber may invade into the transfer chamber.

Further, when a plasma processing such as film formation is performed on the wafer, a radio-frequency power may be supplied to the stage. A support that supports the stage is disposed in the transfer chamber, and the radio-frequency power supplied to the stage is also propagated to the support. As a result, abnormal discharge may occur in the transfer chamber due to the radio-frequency power propagated to the support and the gas or the particles invading into the transfer chamber. Further, as the frequency or the power of the radio-frequency power used for the plasma processing become higher, the conditions for occurring discharge are more likely to be met, and thus, abnormal discharge is more likely to occur in the transfer chamber.

Therefore, the present disclosure provides a technology capable of suppressing the abnormal discharge in the processing container.

[Configuration of Film Forming Apparatus 1]

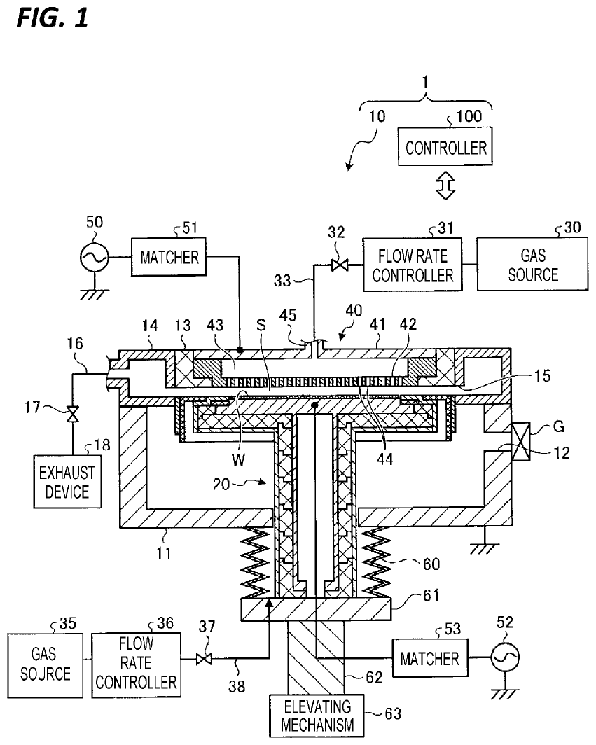

FIG. 1 is a schematic cross-sectional view illustrating an example of a film forming apparatus 1 according to an embodiment of the present disclosure. The film forming apparatus 1 is an apparatus that forms a predetermined film on a semiconductor wafer (hereinafter, referred to as a wafer W), which is an example of a workpiece, by using plasma. The film forming apparatus 1 is an example of a plasma processing apparatus.

The film forming apparatus 1 includes an apparatus body 10 and a controller 100. The apparatus body 10 includes a processing container 11 that is a vacuum container in which the wafer W is accommodated, and film formation is performed on the accommodated wafer W. The processing container 11 is made of a metal such as aluminum, and has a substantially flat circular shape. The processing container 11 is grounded. An opening 12 is formed in a side wall of the processing container 11 to carry in or carry out the wafer W. The opening 12 is opened/closed by a gate valve G.

An exhaust duct 14 is provided above the cover 12. The exhaust duct 14 forms a part of the side wall of the processing container 11, has a hollow angular shape in the vertical cross-section, and is configured to be curved in an annular shape along the side wall of the processing container 11. A slit-shaped exhaust port 15 extending along the extending direction of the exhaust duct 14 is formed on an inner peripheral surface of the exhaust duct 14. Further, one end of an exhaust pipe 16 is connected to the exhaust duct 14. The other end of the exhaust pipe 16 is connected to an exhaust device 18. Further, a pressure adjusting unit 17 such as an auto pressure controller (APC) valve is provided in the exhaust pipe 16. The pressure adjusting unit 17 is controlled by the controller 100, and controls the pressure in the processing container 11 to a predetermined pressure. In the embodiment, the pressure in the processing container 11 is controlled to, for example, several Torr to several tens Torr.

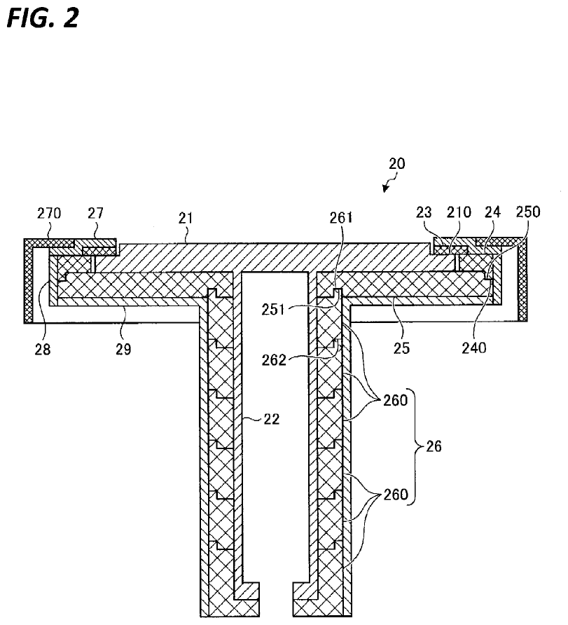

An electrode structure 20 is provided in the processing container 11 to place the wafer W thereon. FIG. 2 is a schematic cross-sectional view illustrating an example of the electrode structure 20 according to the present disclosure. For example, as illustrated in FIG. 2, the electrode structure 20 according to the embodiment includes a stage 21 and a support 22. The stage 21 is made of, for example, a metal such as aluminum, and the wafer W is placed on the upper surface thereof. The support 22 is made of, for example, a metal such as aluminum in a tubular shape, and supports substantially the center of the stage 21 from below.

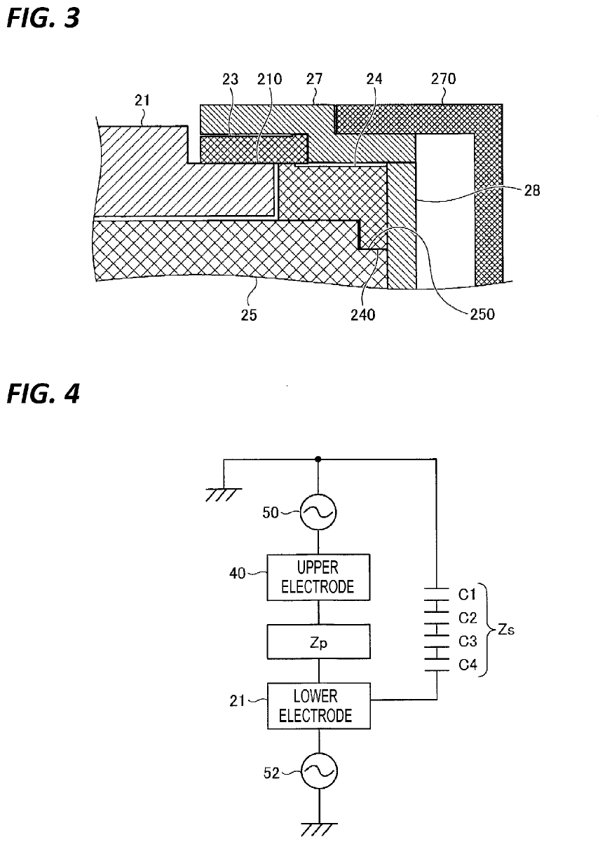

FIG. 3 is an enlarged cross-sectional view illustrating an example of a structure in the vicinity of a peripheral edge of the stage 21. A step 210 is formed along the peripheral edge of the stage 21 on the upper surface of the stage 21 and around the wafer W placed on the stage 21. The step 210 is an example of a peripheral edge region of the upper surface of the stage 21. An annular dielectric 23 is disposed on the step 210. Further, an annular dielectric 24 is disposed on the side surface of the stage 21, and an annular dielectric 25 is disposed on the lower surface of the stage 21.

An annular step 240 is formed on the lower surface of the dielectric 24, which is a surface in contact with the dielectric 25. Further, an annular step 250 is formed on the upper surface of the dielectric 25, which is a surface in contact with the dielectric 24. The step 240 and the step 250 have a shape that fits each other.

An annular dielectric 26 is disposed around the support 22. The dielectric 26 is divided into a plurality of partial dielectrics 260 along the extending direction of the support 22. The dielectric 26 may be formed in a tubular shape according to the shape of the support 22 by one member. However, when the dielectric 26 is made of one member, a temperature gradient may occur in the dielectric 26 when the temperature of the dielectric 26 increases. When the temperature gradient occurs, stress is locally concentrated on a part of the dielectric 26 due to the difference in the coefficient of thermal expansion, and the dielectric 26 may be deformed or damaged. Meanwhile, in the embodiment, the dielectric 26 is divided into a plurality of partial dielectrics 260, and thus, stress may be distributed. Therefore, it is possible to suppress the deformation or the breakage of the dielectric 26.

An annular step 251 is formed on the lower surface of the dielectric 25, which is a surface of the dielectric 25 in contact with the uppermost partial dielectric 260. Further, a step 261 is formed on the upper surface of each partial dielectric 260. Further, a step 262 is formed on the lower surface of each partial dielectric 260, except for the lowermost partial dielectric 260. The step 251 and the step 261 have a shape that fits each other. Further, the step 261 and the step 262 have a shape that fits each other.

In this manner, in the embodiment, the dielectric 24, the dielectric 25, and the plurality of partial dielectrics 260 each have a step on the contact surface with the adjacent dielectrics. Therefore, it is possible to extend the surface distance from the stage 21 or the support 22 to a shield through the boundary surface of the adjacent dielectrics. Therefore, creeping discharge at the boundary surface of the adjacent dielectrics may be suppressed.

The dielectric 23 is an example of a first dielectric, the dielectric 24 and the dielectric 25 are examples of a second dielectric, and the dielectric 26 is an example of a third dielectric.

An annular peripheral ring 27 made of a conductive material is disposed on the upper surface of the dielectric 23 and around the wafer W placed on the stage 21. A tubular shield 28 made of a conductive material is disposed at the position on the side surface of the stage 21 across the dielectric 24. The shield 28 is electrically connected to the peripheral ring 27.

A shield 29 made of a conductive material is disposed on the lower surface of the stage 21 and around the support 22 across the dielectric 25 and the dielectric 26. The shield 29 is electrically connected to the shield 28 and a flange 61, and is grounded via the flange 61.

In the embodiment, the shield 29 is formed by one member, but the technology disclosed is not limited thereto. In another aspect, the shield 29 may be divided into a plate-shaped shield disposed on the lower surface of the stage 21 across the dielectric 25, and a tubular shield disposed around the support 22 across the dielectric 26. However, in this case, the two shields are electrically connected to each other.

The peripheral ring 27 is an example of a first shield, the shield 28 is an example of a second shield, and the shield 29 is an example of a third shield.

A cover member 270 made of a dielectric is provided around the peripheral ring 27 and the shield 28. Although not illustrated, for example, the stage 21 is embedded with a heater configured to adjust the temperature of the wafer W, or an electrode configured to electrostatically adsorb the wafer W on the upper surface of the stage 21 by electrostatic force.

The description will be continued by referring back to FIG. 1. A lower portion of the electrode structure 20 penetrates an opening formed on the bottom portion of the processing container 11. The flange 61 made of a conductive material is provided on the lower end of the electrode structure 20. An upper end of a shaft 62 is connected to substantially the center of the lower surface side of the flange 61. A lower end of the shaft 62 is connected to an elevating mechanism 63. The shaft 62 moves up and down by the elevating mechanism 63, and thus, the electrode structure 20 moves up and down integrally with the flange 61.

For example, the electrode structure 20 is lowered to a transfer position, which is a lower position, by the elevating mechanism 63, and a wafer W, which is not processed, is carried into the processing container 11 by a transfer mechanism (not illustrated) through the opening 12, and is placed on the electrode structure 20. Then, the electrode structure 20 is raised to a processing position, which is an upper position, by the elevating mechanism 63, and then, a film forming processing is performed on the wafer W on the electrode structure 20. Then, the electrode structure 20 is lowered again to the transfer position by the elevating mechanism 63, and the processed wafer W is carried out from the processing container 11 by the transfer mechanism (not illustrated) through the opening 12. When the electrode structure 20 is at the processing position, the space above the stage 21 is the processing chamber, and the space below the stage 21 is the transfer chamber.

The bottom portion of the processing container 11 and the flange 61 are connected with each other by a metal bellows 60. Therefore, even when the electrode structure 20 moves up and down by the elevating mechanism 63, the airtightness in the processing container 11 is maintained. The bellows 60 and the flange 61 are grounded via the processing container 11.

A gas source 35 is connected between the bellows 60 and the electrode structure 20 to supply a purge gas through a pipe 38. The gas source 35 supplies, for example, an inert gas such as a nitrogen gas or a rare gas as a purge gas between the bellows 60 and the electrode structure 20. A flow rate controller 36 and a valve 37 are provided in the pipe 38. When the valve 37 is controlled to an opened state, the flow rate controller 36 controls the flow rate of the purge gas supplied from the gas source 35 between the bellows 60 and the electrode structure 20.

The purge gas is supplied between the bellows 60 and the electrode structure 20 from below, and thus, the particles invading from a gap between the bottom portion of the processing container 11 and the electrode structure 20 are suppressed. Therefore, discharge or re-scattering of the particles between the bellows 60 and the electrode structure 20 may be suppressed.

A radio-frequency power supply 52 is electrically connected to the stage 21 of the electrode structure 20 via a matcher 53. The radio-frequency power supply 52 is a power supply for ion attraction (bias), and supplies a radio-frequency power in a range of 300 kHz to 13.56 MHz, for example, a radio-frequency power of 2 MHz to the stage 21 of the electrode structure 20. The matcher 53 matches a load impedance with an internal (or output) impedance of the radio-frequency power supply 52. The radio-frequency power supply 52 is an example of a power supply.

A shower head 40 is provided inside the annular exhaust duct 14 via the dielectric 13. A ceiling of the processing container 11 is constituted by the dielectric 13 and the shower head 40. The shower head 40 includes an upper plate 41 and a shower plate 42. The upper plate 41 and the shower plate 42 are made of, for example, a metal such as nickel.

The upper plate 41 holds the shower plate 42 detachably from above. The shower plate 42 is provided below the upper plate 41 to face the stage 21 of the electrode structure 20. The shower plate 42 is provided on the lower surface of the upper plate 41, and covers the entire lower surface of the upper plate 41. A recess is provided substantially at the center of the shower plate 42. The shower plate 42 is formed with a plurality of discharge ports 44 that penetrates the shower plate 42 in the thickness direction of the shower plate 42.

A gas introducing port 45 is provided substantially at the center of the upper surface side of the upper plate 41 to introduce a gas into the shower head 40. The gas introduced into the shower head 40 through the gas introducing port 45 is diffused in a diffusion chamber 43 surrounded by the upper plate 41 and the recess of the shower plate 42. The gas diffused in the diffusion chamber 43 is supplied in a shower shape into a processing space S surrounded by the lower surface of the shower plate 42 and the wafer W placed on the electrode structure 20 through the plurality of discharge ports 44. The shower head 40 may be provided with a temperature control mechanism that controls the temperature of the shower head 40.

A gas source 30 is connected to the gas introducing port 45 via a pipe 33. The gas source 30 is a source for the gas used for a film forming processing. A flow rate controller 31 and a valve 32 are provided in the pipe 33. When the valve 32 is controlled to an opened state, the flow rate controller 31 controls the flow rate of the gas flowing from the gas source 30 to the pipe 33.

A radio-frequency power supply 50 is connected to the shower head 40 via a matcher 51. The radio-frequency power supply 50 is a power supply for plasma generation, and generates a radio-frequency power having a frequency of 13.56 MHz or higher, for example, 60 MHz. The radio-frequency power generated by the radio-frequency power supply 50 is supplied to the shower head 40 via the matcher 51. The matcher 51 matches the load impedance with an internal (or output) impedance of the radio-frequency power supply 50.

The radio-frequency power supplied to the shower head 40 is propagated from the upper plate 41 to the shower plate 42, and is radiated from the lower surface of the shower plate 42 into the processing container 11. The gas supplied into the processing space S through the plurality of discharge ports 44 is turned into plasma by the radio-frequency power irradiated into the processing container 11. Then, ions in the plasma are attracted to the wafer W by the radio-frequency power for bias supplied to the stage 21. Therefore, a predetermined film is stacked on the wafer W by the charged particles and active species included in the plasma.

The shower plate 42 and the electrode structure 20 paired with each other, and function as counter electrodes to form a capacitively coupled plasma (CCP) in the processing space S. The shower plate 42 functions as, for example, an upper electrode, and the electrode structure 20 functions as, for example, a lower electrode.

The controller 100 includes a processor, a memory, and an input/output interface. The memory stores a program or a processing recipe. The processor executes the program read from the memory to control each component of the apparatus body 10 via the input/output interface according to the processing recipe read from the memory.

Here, when a radio-frequency power is supplied to the stage 21, the radio-frequency power propagates the surface of the support 22. If the support 22 is not covered with a conductive shield, abnormal discharge occurs between the support 22 and the ground potential member when the pressure in the processing container 11 or the distance between the support 22 and the ground potential member meets the condition for discharge. When the abnormal discharge occurs, the plasma generated in the processing space S becomes unstable, and the quality of the film formed on the wafer W may be deteriorated. Further, due to the abnormal discharge, the members of the film forming apparatus 1 may be deteriorated.

Meanwhile, in the embodiment, the stage 21 and the support 22 are covered with a conductive shield across the dielectrics, and the shield is grounded. Therefore, the abnormal discharge is suppressed from occurring between the support 22 and the ground potential member. Therefore, it is possible to suppress the deterioration of the quality of the film formed on the wafer W.

Further, in order to prevent deformation or breakage due to thermal expansion, a slight gap is provided between the adjacent components in the electrode structure 20. As a result, during the film forming processing, the peripheral ring 27 and the shield 28 are partially in contact with each other and are electrically connected with each other, but a slight gap may remain. The same applies to the contact surface between the shield 28 and the shield 29, and the contact surface between the shield 29 and the flange 61.

Here, an equivalent circuit during the film forming processing is, for example, as illustrated in FIG. 4. FIG. 4 is a view illustrating an example of the equivalent circuit. In FIG. 4, C1 indicates a capacitance between the stage 21 and the peripheral ring 27, and C2 indicates a capacitance between the peripheral ring 27 and the shield 28. Further, C3 indicates a capacitance between the shield 28 and the shield 29, and C4 indicates a capacitance between the shield 29 and the flange 61. Further, Zs indicates an impedance determined by the capacitances C1 to C4, and Zp indicates an impedance of the plasma generated in the processing space S.

In the embodiment, the connection of each shield is adjusted such that the impedance Zs of the shield is larger than the impedance Zp of the plasma. As a result, discharge is performed via the plasma instead of the shield. Therefore, abnormal discharge via the shield is suppressed. The impedance Zs of the shield may be twice or more the impedance Zp of the plasma. Therefore, it is possible to effectively suppress the abnormal discharge via the shield.

In the above, one embodiment has been described. As described above, the film forming apparatus 1 according to the embodiment includes the processing container 11, the shower head 40, the electrode structure 20, and the radio-frequency power supply 52. The shower head 40 is disposed in the processing container 11, functions as an upper electrode, and supplies a gas used to generate plasma into the processing container 11. The electrode structure 20 is disposed in the processing container 11, and has the upper surface on which the wafer W is placed. The radio-frequency power supply 52 supplies a radio-frequency power to the electrode structure 20. Further, the electrode structure 20 includes the stage 21, the support 22, the dielectric 23, the dielectric 24, the dielectric 25, the dielectric 26, the peripheral ring 27, the shield 28, and the shield 29. The stage 21 functions as a lower electrode facing the shower head 40, and has the upper surface on which the wafer W is placed. The support 22 is connected to the lower portion of the stage 21, and supports the stage 21. The dielectric 23 is disposed in the peripheral edge region of the upper surface of the stage 21. The dielectric 24 is disposed on the side surface of the stage 21. The dielectric 25 is disposed on the lower surface of the stage 21. The dielectric 26 is disposed around the support. The peripheral ring 27 is disposed on the upper surface of the dielectric 23 and on the peripheral edge of the stage 21. The shield 28 is connected to the peripheral ring 27, and is disposed on the side surface of the stage 21 across the dielectric 24. The shield 29 is connected to the shield 28, and is disposed on the lower surface of the stage 21 and around the support 22 across the dielectric 25 and the dielectric 26. Further, plasma is generated between the shower head 40 and the stage 21, and the wafer W placed on the stage 21 is processed by the generated plasma. Further, the shield 29 is grounded. Therefore, the abnormal discharge is suppressed from occurring between the stage 21 and the support 22 and the ground potential member. Therefore, it is possible to suppress the deterioration of the quality of the film formed on the wafer W.

Further, in the above-described embodiment, the impedance Zs between the stage 21 and the ground potential via the peripheral ring 27, the shield 28, and the shield 29 is larger than the impedance Zp between the shower head 40 and the stage 21 via the plasma generated between the shower head 40 and the stage 21. Therefore, discharge is likely to occur in the plasma than between the shield and the ground potential, and thus, the abnormal discharge via the shield is suppressed.

Further, in the embodiment, the impedance Zs may be twice or more the impedance Zp. Therefore, discharge is more likely to occur in the plasma than between the shield and the ground potential, and thus, the abnormal discharge via the shield is suppressed more effectively.

Further, in the embodiment, the support 22 has a tubular shape, and the dielectric 26 is divided into a plurality of partial dielectrics 260 along the extending direction of the support 22. In each partial dielectric 260, a step is formed in the surface in contact with another adjacent partial dielectric 260. Further, the step 261 and the step 262 formed in the contact surfaces of two partial dielectrics 260 that are in contact with each other have a shape that fits each other. Therefore, creeping discharge at the boundary surface of the adjacent dielectrics may be suppressed.

[Others]

Further, the technique disclosed in the present disclosure is not limited to the above-described exemplary embodiment, and various modifications may be made within the scope of the disclosure.

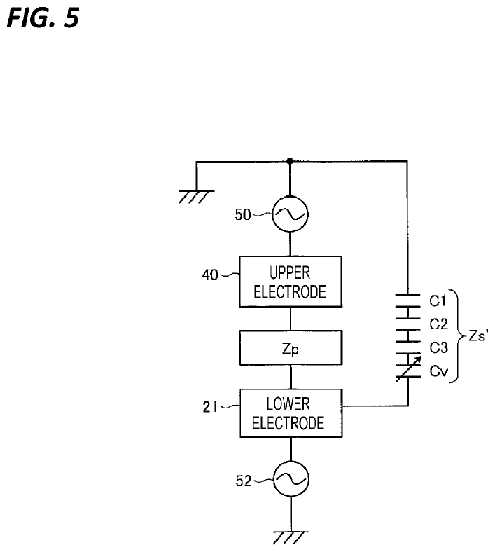

For example, in the above-described embodiment, the impedance Zs of the shield between the stage 21 and the ground potential is an impedance determined by the capacitances C1 to C4, but the disclosed technology is not limited thereto. For example, the shield 29 may be connected to the flange 61 via a variable capacitance capacitor. In this case, an equivalent circuit during the film forming processing is, for example, as illustrated in FIG. 5. FIG. 5 is a view illustrating another example of the equivalent circuit.

In FIG. 5, Cv indicates a capacitance of a variable capacitance capacitor disposed between the shield 29 and the flange 61, and Zs' indicates an impedance determined by the capacitances C1 to C3 and the capacitance Cv. In the example of FIG. 5, it is possible to control the distribution of the plasma by changing the value of the capacitance Cv in a range that satisfies the condition Zp<Zs′. However, even in this case, the impedance Zs' of the shield may be twice or more the impedance Zp of the plasma.

Further, in the above-described embodiment, although the film forming apparatus 1 has been described as an example, the disclosed technology may be applied to, for example, an etching device, a reforming device, or a cleaning device, as long as the device performs a processing using plasma.

Further, in the above-described embodiment, although a radio-frequency power for plasma generation is supplied to the shower head 40, the disclosed technology is not limited thereto. As another embodiment, a radio-frequency power for plasma generation may be supplied to the stage 21. Further, as the other embodiment, it may be configured such that a radio-frequency power for plasma generation is supplied to the stage 21, but a radio-frequency power for bias is not supplied thereto.

Further, in the above-described embodiment, although a capacitively coupled plasma (CCP) is used as an example of a plasma source, the disclosed technology is not limited thereto. Examples of the plasma source may include an inductively coupled plasma (ICP), a microwave excited surface wave plasma (SWP), an electron cyclotron resonance plasma (ECP), and a helicon wave excited plasma (HWP).

It should be considered that the embodiments disclosed in here are exemplary and not restrictive in all aspects. In practice, the embodiments described above may be implemented in various forms. Further, the above-described embodiments may be omitted, replaced, or changed in various forms without departing from the scope of accompanying claims and the gist thereof.

### DESCRIPTION OF SYMBOLS

S: processing space
W: wafer
1: film forming apparatus
10: apparatus body
11: processing container
20: electrode structure
21: stage
210: step
22: support
23: dielectric
24: dielectric
240: step
25: dielectric
26: dielectric
27: peripheral ring
28: shield
29: shield
40: shower head
41: upper plate
40: shower plate
50: radio-frequency power supply
52: radio-frequency power supply
60: bellows
61: flange
62: shaft
63: elevating mechanism
100: controller

1. A plasma processing apparatus comprising:
a processing container;
a shower head disposed in the processing container serving as an upper electrode, and configured to supply a gas used to generate plasma into the processing container;
an electrode disposed in the processing container and includes having an upper surface on which a workpiece is placed; and
a power supply configured to supply a radio-frequency power to the electrode,
wherein the electrode includes:
a stage facing the shower head to serve as a lower electrode, and having an upper surface on which the workpiece is placed;
a support connected to a lower portion of the stage and configured to support the stage;
a first dielectric disposed in a peripheral edge region of the upper surface of the stage;
a second dielectric disposed on a side surface and a lower surface of the stage;
a third dielectric disposed around the support;
a first shield serving as an upper surface of the first dielectric, and disposed in the peripheral edge of the stage;
a second shield connected to the first shield, and disposed on the side surface of the stage across the second dielectric; and
a third shield connected to the second shield, and disposed on the lower surface of the stage and around the support across a part of the second dielectric and the third dielectric,
plasma is generated between the shower head and the stage, and the workpiece placed on the stage is processed by the plasma, and
the third shield is grounded.

2. The plasma processing apparatus according to claim 1, wherein an impedance Zs between the stage and a ground potential via the first shield, the second shield, and the third shield is larger than an impedance Zp between the shower head and the stage via the plasma generated between the shower head and the stage.

3. The plasma processing apparatus according to claim 2, wherein the impedance Zs is twice or more the impedance Zp.

4. The plasma processing apparatus according to claim 1 wherein the support has a tubular shape,
the third dielectric is divided into a plurality of partial dielectrics along an extending direction of the support,
each of the plurality of partial dielectrics has a step formed on a surface thereof in contact with adjacent partial dielectrics, and
steps formed on surfaces of two partial dielectrics that are in contact with each other have a shape that fits each other.

5. The substrate processing apparatus according to claim 1, wherein the third shield is grounded via a variable capacitor.

6. An electrode structure comprising:
a stage facing an upper electrode to serve as a lower electrode, and having an upper surface on which a workpiece is placed;
a support connected to a lower portion of the stage and configured to support the stage;
a first dielectric disposed in a peripheral edge region of the upper surface of the stage;
a second dielectric disposed on a side surface and a lower surface of the stage;
a third dielectric disposed around the support;
a first shield serving as an upper surface of the first dielectric, and disposed in the peripheral edge of the stage;
a second shield connected to the first shield, and disposed on the side surface of the stage across the second dielectric; and
a third shield connected to the second shield, and disposed on the lower surface of the stage and around the support across a part of the second dielectric and the third dielectric,
wherein the third shield is grounded.
